(19) United States
(12) Patent Application Publication
(10) Pub. No.: US 2017/0271185 A1
(43) Pub. Date: Sep. 21, 2017

(54) Thin Film Device Fabrication Methods and Apparatus

(71) Applicant: KATHOLIEKE UNIVERSITEIT LEUVEN, Leuven (BE)

(72) Inventors: Jean-Pierre LOCQUET, Haasrode (BE); Chen-Yi SU, Taoyuan City (TW)

(73) Assignee: Katholieke Universiteit Leuven, Leuven (BE)

(21) Appl. No.: 15/500,221

(22) PCT Filed: Jul. 31, 2015
(86) PCT No.: PCT/EP2015/067758

§ 371 Date: Jan. 30, 2017

Related U.S. Application Data
(60) Provisional application No. 62/031,764, filed on Jul. 31, 2014.

(51) Int. Cl. H01L 21/67; C30B 23/00; C30B 23/02; C30B 29/16; C30B 29/20; H01L 21/02; C30B 33/02

(52) U.S. Cl. CPC H01L 21/67253; H01L 21/02178; H01L 21/022; H01L 21/02318; C30B 23/002; C30B 33/02; C30B 29/16; C30B 29/20; C30B 23/02

(57) ABSTRACT

A deposition device for providing a thin film on a substrate. The device comprises a material source for providing at least one first metallic element which does not re-evaporate substantially from the substrate under particular growth conditions, at least one second metallic element or metal based molecule which does re-evaporate substantially from the substrate under the same growth conditions, and a component suitable for forming an at least one first compound with the at least one first metallic element and an at least one second compound with the at least one second metallic element or metal based molecule. The device comprises a controller configured to control the growth conditions, and the amounts of the at least one first metallic element, the at least one second metallic element or metal based molecule, and the component so as to obtain a substantially stoichiometric thin film.

### FIELD OF THE INVENTION

The present invention relates to thin film device fabrication methods and apparatuses. More specifically the present invention relates to methods and devices for manufacturing thin films for general applications in electronics, photonics, materials engineering, surface engineering and energy related applications.

### BACKGROUND OF THE INVENTION

Thin films are currently made by many different methods, such as Physical Vapour Deposition (PVD), Chemical Vapour Deposition (CVD), Sol-Gel Deposition (SGD), Atomic Layer Deposition (ALD), Pulsed Laser Deposition (PLD) and Molecular Beam Epitaxy (MBE) to name a few. However, all the processes that are typically used to deposit these compound thin films are very far from thermodynamic equilibrium. Or put in another words, the conditions under which high quality and stoichiometric single crystals of compounds are grown, are very different from the conditions under which thin films of the same compounds are grown.

The known methods can be divided into two groups. In a first group, a single metallic target is used (PVD, PLD) and additional gaseous species are aimed to the target and to the substrate. For instance, in the case of oxide growth, oxide species (atoms, molecules, ions or a combination) are supplied in addition to the metal emanating from the target, and in the case of nitride growth nitrogen species are supplied. The target can consist of a single material but can also be a compound in the second group. This compound can be an oxide or a nitride, etc. In most cases however additional gaseous species are necessary to get a thin film near the stoichiometric composition of the compound. In other methods, only a single species is supplied to the substrate and then it is reacted. For instance in the case of MBE, typically a metallic vapour is supplied to the substrate, under a flow of molecular or atomic species of oxygen, nitrogen, etc. In ALD, typically a chemical precursor is supplied to the substrate first leading to a “quasi”-monolayer coverage, and then a reactive species is supplied which then leads to the formation of the desired compound. In CVD—which is typically a high temperature deposition process—a similar process is used but in this case it is the high temperature that decomposes the chemical precursor and the compound is formed subsequently through reactions with the supplied gases.

The consequence of being far off thermodynamic conditions is that the quality of these films is rather poor. Indeed, typically these films have a lower density (up to 10%) compared to their bulk counterparts. Also there is typically a significant off-stoichiometry of a few percent, which leads to significant quality issues in the further use of such films. In the case of oxide films two cases can be distinguished. For instance the oxide films are frequently oxygen deficient due to low temperature and low pressure growth. Alternatively the films can also be oxygen rich under sufficiently high pressure or if a reactive source of oxygen is used.

Therefore there is a need for novel thin film device fabrication methods and apparatus, to overcome at least some of the disadvantages mentioned.

### SUMMARY OF THE INVENTION

It is an object of embodiments of the present invention to provide a deposition device and method for providing a good, e.g. an improved, thin film on a substrate.

The above objective is accomplished by a method and device according to the present invention.

In a first aspect the present invention provides a deposition device for providing a thin film on a substrate. The device comprises a material source for providing at least one first metallic element which does not re-evaporate substantially from the substrate under particular growth conditions, at least one second metallic element or metal based molecule which does re-evaporate substantially from the substrate under the same growth conditions, and a component suitable for forming an at least one first compound with the at least one first metallic element and an at least one second compound with the at least one second metallic element or with the metal based molecule. The device moreover comprises a controller configured to control the growth conditions, and the amounts of the at least one first metallic element, the at least one second metallic element or metal based molecule, and the component so as to obtain a substantially stoichiometric thin film of the at least one first compound and of the at least one second compound on the substrate.

It is an advantage of embodiments of the present invention that the process window for obtaining a substantially stoichiometric thin film increases, or that the stoichiometry of the obtained thin film increases, when the second metallic element or metal based molecule is added in the manner. It is an advantage of embodiments of the present invention that, by providing the at least one second metallic element or metal based molecule, the activity (species diffusion, mobility, surfactant behaviour etc) during the thin film growth process can be is increased. In embodiments of the present invention the at least one second metallic element or metal based molecule re-evaporates from the substrate under the growth conditions so that in these embodiments at least two dynamic species are present during the growth and conditions closer to the thermodynamic equilibrium can be obtained. The two species are the second metallic species and the component since both may re-evaporate from the surface. It is an advantage of embodiments of the present invention that they allow to create well defined stoichiometric ratios between metallic species and component species. For instance in a particular embodiment of the present invention the ratio (Al+Mg) versus O can be well controlled and whereas the ratio Al vs Mg cannot be controlled as good. It is an advantage of embodiments of the present invention that by adding the second metallic element or metal based molecule, the composition can be changed from component (e.g. oxygen) rich to component (e.g. oxygen) poor. This additionally offers the option to change the carrier type from for instance n-type to p-type. It is an advantage of embodiments of the present invention that a stoichiometric excess of the second metallic element or metal based molecule will result in second metallic elements or metal based molecules which are not formed into a second compound (e.g. non-oxidized second metallic elements) and which will re-evaporate from the substrate whereas the second metallic elements or metal based molecules which are formed into a second compound will not evaporate from the substrate at the same growth conditions. It is an advantage of embodiments of the present invention that this increases the process window with regard to the concentration of the component (e.g. oxygen) which needs to be applied to obtain a substantially stoichiometric thin film.

In embodiments of the present invention the controller is configured to provide an annealing step after providing the thin film on the substrate.

It is an advantage of embodiments of the present invention that the stoichiometry of the thin film is increased by providing an annealing step. It is an advantage of embodiments of the present invention that the second metallic elements or metal based molecules which are not bound in a compound (e.g. the non-oxidized ones) will evaporate from the substrate. In embodiments of the present invention substrate temperature and the annealing properties used for specific elements are adapted for these elements.

In embodiments of the present invention the controller is configured to alternatingly provide the at least one second metallic element or metal based molecule and combinations of the at least one second metallic element or metal based molecule and the at least one first metallic element, and/or alterations of the component flux, so as to obtain component rich and component deficient states.

It is an advantage of embodiments of the present invention that the surfactant properties of the volatile at least one second metallic element or metal based molecule can be used. The surfactant behaviour can control whether the film will grow flat or in islands.

In embodiments of the present invention the controller is configured to change the temperature during the alternations.

It is an advantage of embodiments of the present invention that second metallic elements or metal based molecules will be included in the film or evaporated from the substrate to a larger or lesser extent, depending on the temperature. For example by increasing the temperature Mg is evaporated more and by lowering the temperature it is deposited.

In embodiments of the present invention the controller is configured to control the growth conditions in function of the thickness of the film on the substrate.

It is an advantage of embodiments of the present invention that an off-stoichiometric composition of the thin film can be remedied during film growth. It is an advantage of embodiments of the present invention that an excess of an element can be more easily removed before the thin film has grown to its full thickness.

In a second aspect, the present invention provides a method for providing a thin film on a substrate. The method comprises providing at least one first metallic element which does not re-evaporate substantially from the substrate under particular growth conditions, providing at least one second metallic element or metal based molecule which does re-evaporate substantially from the substrate under the same growth conditions, providing a component suitable for forming an at least first compound with the at least one first metallic element and an at least one second compound with the at least one second metallic element or metal based molecule. The method comprises controlling the growth conditions, and the amounts of the at least one first metallic element, of the at least one second metallic element or metal based molecule and of the component so as to obtain a substantially stoichiometric thin film of the at least one first compound and of the at least one second compound on the substrate.

In embodiments of the present invention the method comprises an annealing step after providing the elements and controlling the growth conditions.

In embodiments of the present invention providing the elements is done by alternatingly providing the at least one second metallic element or metal based molecule and combinations of the at least one second metallic element or metal based molecule and the at least one first metallic element.

In embodiments of the present invention controlling the growth conditions comprises changing the substrate temperature during the alterations.

In embodiments of the present invention the controlling step comprises taking into account the thickness of the film on the substrate.

Particular and preferred aspects of the invention are set out in the accompanying independent and dependent claims. Features from the dependent claims may be combined with features of the independent claims and with features of other dependent claims as appropriate and not merely as explicitly set out in the claims.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

The above and other aspects of the invention will be apparent from and elucidated with reference to the embodiment(s) described hereinafter.

### BRIEF DESCRIPTION OF THE DRAWINGS

The invention will now be described further, by way of example, with reference to the accompanying drawings, in which:

FIG. 1 is a schematic drawing of a deposition device for providing a thin film on a substrate in accordance with embodiments of the present invention; and

FIG. 2 shows the different steps in a method for providing a thin film on a substrate in accordance with embodiments of the present invention.

FIG. 3 is a graph wherein the re-evaporation rate in function of the temperature is shown for a metallic element with a high re-evaporation rate and for a metallic element with a low re-evaporation rate.

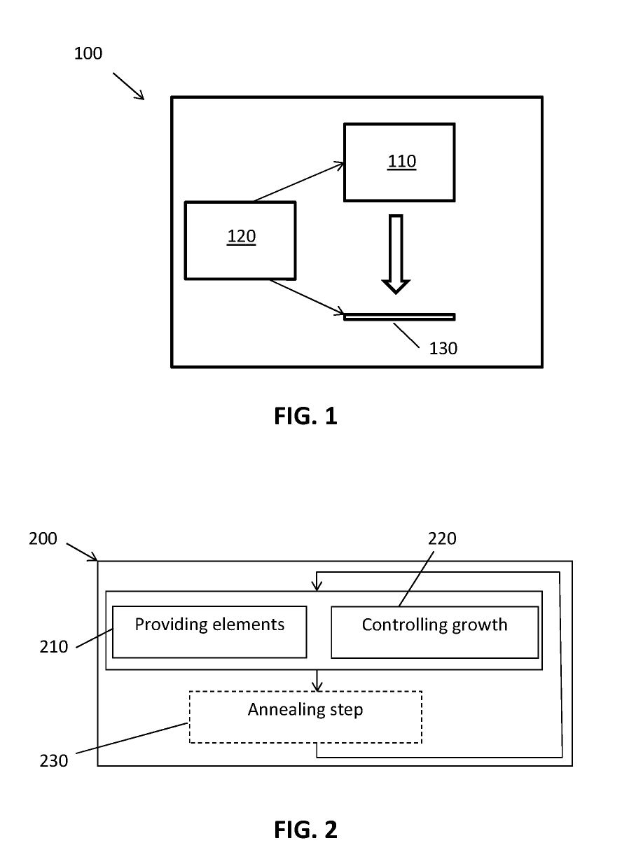

The drawings are only schematic and are non-limiting. In the drawings, the size of some of the elements may be exaggerated and not drawn on scale for illustrative purposes. The dimensions and the relative dimensions do not necessarily correspond to actual reductions to practice of the invention.

Any reference signs in the claims shall not be construed as limiting the scope. In the different drawings, the same reference signs refer to the same or analogous elements.

### DETAILED DESCRIPTION OF ILLUSTRATIVE EMBODIMENTS

The present invention will be described with respect to particular embodiments and with reference to certain drawings but the invention is not limited thereto but only by the claims. The drawings described are only schematic and are non-limiting. In the drawings, the size of some of the elements may be exaggerated and not drawn on scale for illustrative purposes. The dimensions and the relative dimensions do not correspond to actual reductions to practice of the invention.

The terms first, second and the like in the description and in the claims, are used for distinguishing between similar elements and not necessarily for describing a sequence, either temporally, spatially, in ranking or in any other manner. It is to be understood that the terms so used are interchangeable under appropriate circumstances and that the embodiments of the invention described herein are capable of operation in other sequences than described or illustrated herein.

Moreover, the terms top, under and the like in the description and the claims are used for descriptive purposes and not necessarily for describing relative positions. It is to be understood that the terms so used are interchangeable under appropriate circumstances and that the embodiments of the invention described herein are capable of operation in other orientations than described or illustrated herein.

It is to be noticed that the term “comprising”, used in the claims, should not be interpreted as being restricted to the means listed thereafter; it does not exclude other elements or steps. It is thus to be interpreted as specifying the presence of the stated features, integers, steps or components as referred to, but does not preclude the presence or addition of one or more other features, integers, steps or components, or groups thereof. Thus, the scope of the expression “a device comprising means A and B” should not be limited to devices consisting only of components A and B. It means that with respect to the present invention, the only relevant components of the device are A and B.

Reference throughout this specification to “one embodiment” or “an embodiment” means that a particular feature, structure or characteristic described in connection with the embodiment is included in at least one embodiment of the present invention. Thus, appearances of the phrases “in one embodiment” or “in an embodiment” in various places throughout this specification are not necessarily all referring to the same embodiment, but may. Furthermore, the particular features, structures or characteristics may be combined in any suitable manner, as would be apparent to one of ordinary skill in the art from this disclosure, in one or more embodiments.

Similarly it should be appreciated that in the description of exemplary embodiments of the invention, various features of the invention are sometimes grouped together in a single embodiment, figure, or description thereof for the purpose of streamlining the disclosure and aiding in the understanding of one or more of the various inventive aspects. This method of disclosure, however, is not to be interpreted as reflecting an intention that the claimed invention requires more features than are expressly recited in each claim. Rather, as the following claims reflect, inventive aspects lie in less than all features of a single foregoing disclosed embodiment. Thus, the claims following the detailed description are hereby expressly incorporated into this detailed description, with each claim standing on its own as a separate embodiment of this invention.

Furthermore, while some embodiments described herein include some but not other features included in other embodiments, combinations of features of different embodiments are meant to be within the scope of the invention, and form different embodiments, as would be understood by those in the art. For example, in the following claims, any of the claimed embodiments can be used in any combination.

In the description provided herein, numerous specific details are set forth. However, it is understood that embodiments of the invention may be practiced without these specific details. In other instances, well-known methods, structures and techniques have not been shown in detail in order not to obscure an understanding of this description.

A stoichiometric compound has an elemental composition whose proportions can be represented by integers (e.g. Al2O3, MgO). Where in embodiments of the present invention reference is made to a substantially stoichiometric thin film, reference is made to a thin film in which defects are present because no perfect stoichiometry is obtained in the thin film. The substantially stoichiometric film obtained using a device according to the present invention has the same or less defects than a thin film which is made without adding at least one second metallic element or metal based molecule.

Where in embodiments of the present invention reference is made to at least one first metallic element which does not re-evaporate substantially from the substrate under particular growth conditions and to at least one second metallic element or metal based molecule which does re-evaporate substantially from the substrate under the same growth conditions, reference is made to a first re-evaporation rate of the at least one first metallic element which is lower than the second re-evaporation rate of the at least one second element or metal based molecule. The first re-evaporation rate may for example be at least 2 times smaller than the second re-evaporation rate, or even at least 5 times smaller, or even at least 10 times smaller.

The second metallic element may for example be magnesium (Mg), strontium (Sr), barium (Ba), calcium (Ca) or lithium (Li). It may for example also be arsenic (As), phosphorus (P), antimony (Sb), or tin (Sn). It may for example also be Si. The metal based molecule may be a diatomic (e.g. As2) or triatomic (e.g.; As3) species. An example thereof is As2 which in combination with O results in a second compound As2O3. The metal based molecule may for example also be a molecule comprising one or more metal atoms and additional non-metal atoms, such as for example SiO, GeO and GeO2, WO3, InN, AsH3, or PH4. More elaborate molecules are those molecules know under the broad name of metal-organic molecules that are used in chemical vapour deposition processes such as Mg(THMD)2 Bis(2,2,6,6-tetramethyl-3,5-heptanedionato)magnesium dehydrate or for silicon TEOS (Tetraethoxysilane). These molecules will also react with the component under the appropriate conditions.

Where in embodiments of the present invention reference is made to the process window for obtaining a thin film, reference is made to the growth conditions (e.g. temperature, pressure, flux, evaporation rate, deposition rate) and to the amounts of elements (first elements, second elements, component) which are added.

In a first aspect, the present invention provides a deposition device 100 for providing a thin film on a substrate 130.

The deposition device 100 comprises a material source 110 for providing:

at least one first metallic element which does not re-evaporate substantially from the substrate 130 under particular growth conditions,

at least one second metallic element or metal based molecule which does re-evaporate substantially from the substrate 130 under the same growth conditions, and

a component suitable for forming a first compound with the at least one first element and a second compound with the at least one second metallic element or with the metal based molecule. The thin film formed on the substrate is formed by a combination of the first and second compounds.

As an example only, for illustrating embodiments of the present invention, it may be desired to grow a thin film of Al2O3 on a semiconductor substrate. In this example, Al2O3 is the first compound. To obtain a defect-free film, the provided quantities of Al (first metallic element) and O (component), hence the relative pressures of Al and O, need to be very precisely aligned, such that for every 2 Al atoms 3 O atoms are available. If the amount of O atoms is too small, unoxidized Al will be present in the thin film, which will deteriorate the film properties. If the amount of O atoms is too large, interstitial oxygen may be present. In general it is difficult to find the conditions where the ratio 2 to 3 is perfectly respected. It has been found by the inventors of the present invention that the stoichiometric amount of O in a thin film may be much better controlled if at the same time a second metallic element or metal based molecule, such as e.g. Mg, is provided, whereby the Mg atoms form MgO (second compound) with the excess O atoms, and whereby the Mg atoms, if not oxidized, re-evaporate from the substrate. Hence in the end a compound film of Al2O3 with a limited quantity of MgO is formed, but the amounts of unoxidized Al atoms, unoxidized Mg atoms or excess oxygen can be limited in the film.

The above example is given for ease of understanding only; the invention not being limited thereto in any way.

The deposition device 100 moreover comprises a controller 120 for controlling the growth conditions, and the amounts of the at least one first metallic element, the at least one second metallic element or metal based molecule, and of the component suitable for forming the first compound and the second compound, so as to obtain a substantially stoichiometric thin film of the at least one first compound and of the at least one second compound on the substrate 130. The quantity of component suitable for forming the first compound and the second compound should be larger than the stoichiometric quantity required to form the first compound by consuming all first metallic elements present, but smaller than the stoichiometric quantity required to form both the first compound and the second compound by consuming all first and second metallic elements or metal based molecules. The exact quantity of component (e.g. oxygen) provided does not matter, as long as it falls within these margins.

It is an aspect of embodiments of the present invention that, while the first compound is formed, also the second compound is formed, but that under the process conditions at which these compounds are formed, unreacted second metallic elements or metal based molecules which would be present at the substrate surface will evaporate. Hereto, the first metallic element and the second metallic element or metal based molecule should be selected so as to have properties such that the first metallic element does not evaporate substantially from the substrate surface under the process conditions, while the second metallic element or metal based molecule does evaporate substantially. For the materials in example given above, Al evaporates from the substrate at about 1000°, while Mg evaporates from the substrate at about 300°. If the process temperature for growing the film is about 500°, it can be seen that the first metallic element (Al) has an evaporation temperature higher than the process temperature—hence the first metallic element will not evaporate substantially at the process temperature—while the second metallic element (Mg) has an evaporation temperature below 500°—and hence will evaporate substantially at the process temperature.

In embodiments of the present invention the component suitable for forming the first compound and the second compound may be oxygen (O) and/or nitrogen (N) and/or carbon (C) and/or hydrogen (H) and or/arsenic (As) and/or phosphor (P) and/or antimony (Sb) and/or tin (Sn) and in general any element with which compounds can be made (e.g. F, Cl, Se, S, Br, Te).

In embodiments of the present invention the first metallic element is a metallic species that has a low vapour pressure under the growth conditions and will not re-evaporate substantially from the growing surface. Such an element may for example be Aluminum (Al), Hafnium (Hf), Zirconium (Zr), Titanium (Ti).

In embodiments of the present invention the second metallic element or metal based molecule is a metallic species that has a substantial vapour pressure under the growth conditions and will re-evaporate substantially from the growing surface.

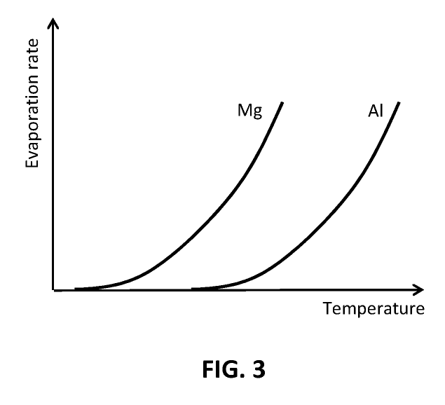

In general a high vapour pressure corresponds with a high re-evaporation rate. FIG. 3 shows the re-evaporation rate in function of temperature for a metallic element with a high re-evaporation rate (this is the left curve; e.g. Mg) and for a metallic element with a low re-evaporation rate (this is the right curve; e.g. Al).

A similar graph can be obtained for gallium (Ga) and indium (In). In this case the substantially stoichiometric thin film is a GaN film. The first metallic element is Ga, the second metallic element is In and the component suitable for forming the first compound and the second compound is GaN. In this case Indium is the element with the high re-evaporation rate (corresponding with the left curve) and Ga is the element with the low evaporation rate (corresponding with the right curve).

In embodiments of the present invention the second metallic element or metal based molecule is selected such that it evaporates under growth conditions at which the substrate does not get damaged. A growth condition parameter may for example be the temperature. In embodiments of the present invention the second metallic element or metal based molecule is selected such that it evaporates from the substrate 130 at a temperature which is below the temperature at which the substrate gets damaged.

In embodiments of the present invention the substrate 130 may comprise semiconductor material. The substrate may for example comprise silicon (Si), germanium (Ge), SiC or a III/V semiconductor material (e.g. GaAs, InGaAs) or may include another layer between the substrate and the material to be grown (interface layer or buffer layer or cap layer or compositionally graded layer like SiGe, etc).

In embodiments of the present invention the second compound in the thin film formed on the substrate 130 is an oxide, a nitride, a carbide, and in general any component with which compounds can be made (e.g. H, As, P, Sb, Sn, F, Cl, Se, S, Br, Te) combinations thereof and all compounds containing any of the second metallic elements (e.g. Mg containing compounds) or metal based molecules. These compounds can be ternary or quaternary compounds that comprise Mg or any of the other second metallic elements or metal based molecules (high vapour pressure elements). Although the overall chemistry of such compounds is more complex, it is an advantage of embodiments of the present invention that the presence of Mg or any other second metallic element or metal based molecule can be used to obtain the correct compound stoichiometry. A ternary, quaternary (or higher) first compound may be comprising a plurality of low vapour pressure first metals and may be combined with a high vapour pressure second metal (e.g. AlHfSiO+Mg). A ternary, quaternary (or higher) second compound may be comprising a plurality of high vapour pressure second metals and may be combined with a low vapour pressure first metal (e.g. AlO+MgSrO). Combinations of ternary, quaternary (or higher) first compounds and ternary, quaternary (or higher) second compounds are also possible.

Where in embodiments of the present invention, second metallic element, e.g. Mg, species or metal based molecules are deposited on the substrate 130 during growing of a film of the first compound, then there is a significant probability for these second metallic element atoms, e.g. the Mg atoms, or metal based molecules to re-evaporate due to the substrate temperature. This process can then be hampered by the supply of component species, e.g. oxide species, either in atomic or molecular form.

In embodiments of the present invention the component (e.g. oxygen/nitrogen/carbon/etc) is added in an amount which is above the stoichiometric amount required for the at least one first metallic element alone and which is below the stoichiometric amount required for the at least one first and the at least one second metallic element or metal based molecule. In embodiments of the present invention the amount of stoichiometry that can be off can be substantial and can be corrected by the amount and vapour pressure of the second metallic element or metal based molecule.

In case the amount of the component is below the stoichiometric amount required for the at least one first and the at least one second metallic element or metal based molecule (e.g. oxygen deficient case), embodiments of the present invention provide that the substrate 130 is heated to a high enough temperature such that the extra at least one second metallic element or metal based molecule (e.g. Mg) which is not converted into the second compound (e.g. MgO) will re-evaporate and not remain on the substrate This can be done carefully using in-situ annealing processes. It is an advantage of embodiments of the present invention that thereby the stoichiometry of the realized thin film gets closer to the required one, thus improving the film properties.

In embodiments of the present invention the controller 120 is preferably configured to control the amounts such that the amount of the component is below the stoichiometric amount required for the at least one first and the at least one second metallic element or metal based molecule (e.g. the oxygen deficient case).

In embodiments of the present invention, the surfactant properties of the volatile second metallic elements or metal based molecules can be used in addition, wherein—in the form of bilayers, gradient layers or multilayers—the deposition of second metallic elements (e.g. Mg metallic species) or metal based molecules can be alternated with the deposition of the combined species so that for instance an alternation between component deficient, e.g. oxygen deficient, and component rich, e.g. oxygen rich, states can be made. The temperature (or any other parameter of the growth conditions) may also be a parameter that is changed during these alternations. In embodiments of the present invention depositing may be done at a lower temperature followed by a higher temperature annealing step.

In embodiments of the present invention the controller 120 is configured to anneal the surface of the substrate 130 after adding the at least one second metallic element (e.g. magnesium) or metal based molecule. It is an advantage of embodiments of the present invention that thereby the substrate 130 can be modified or cleaned. In embodiments of the present invention this may result in the cleanup of the oxide remnants by converting them into MgO. For instance assume that some SiOx is remaining on the Si surface. Then following the deposition of Mg on SiOx and annealing, the surface is converted into Si and MgO. All the extra Mg deposited is then again re-evaporated. The same mechanism applies for the other semiconductors such as Ge, and the III/V materials as well as any other surface layer on the substrate

In embodiments of the present invention the at least one second metallic element or metal based molecule is not present in the compound formula of the at least one first compound. It is an advantage of embodiments of the present invention that a few percent (e.g. less than 10%, or even less than 5%, or even less than 3%, or even 1% or below) of doping of the second metallic element (e.g. Mg doping) or metal based molecule can in general be tolerated to obtain still the desired material properties. For higher doping amount the method still works as well but the properties of the compound may start to vary either in a desired or in an undesired manner. It is thereby an advantage that the introduction of the second metallic element (e.g. Mg) or metal based molecule and its subsequent evaporation can serve as a vehicle to improve the thin film quality (e.g. of the Al₂O₃ film) towards the perfect stoichiometry.

The deposition device 100 according to embodiments of the present invention may have different realizations depending on the choice of source material.

The description below discusses Mg as second metallic element. The present invention is, however, not limited thereto. Even though the description below focuses on Mg/MgO, embodiments of the present invention always comprise a material source for providing at least one first metallic element and for providing at least one second metallic element or metal based molecule and for providing a component suitable for forming the first compound and the second compound. In embodiments of the present invention where magnesium is used as second metallic element and where oxygen is added as component, a MgO thin film may be created using molecular beam epitaxy (MBE). The material source 110 can be Mg metal, for instance from an effusion cell, or it can be a mixture containing Mg/MgO, for instance from an e-beam evaporator or from a high temperature effusion cell. In the former case the addition of molecular or atomic oxygen is necessary to grow MgO films, while in the latter case the addition of gases is less required. The typical temperatures required to evaporate Mg are between 200° C. and 300° C. while those required for MgO are much higher between 1400° C.-1500° C. It is to be noted that also in the latter case, the gases coming out of the MgO material do comprise the following species MgO/Mg/O/O₂ species, which can be measured using for instance a quartz crystal monitor or mass spectrometer. In this case also the deposited MgO as compound does not fit for the role of second metallic element since it will not evaporate nearly as much as Mg does. This is an embodiment that for example can be used as long as the material evaporated from the MgO surface contains enough Mg to play the role of volatile second metallic element.

In yet another embodiment of the present invention the material source 110 may comprise targets of Mg and MgO in conjunction with high energetic beams such as lasers in laser ablation, ions in sputtering and electrons in electron beam guns. Depending on the target used, the same species will come from of the target in addition to the different ionized versions, clusters and complexes. Hence the same ideas can be applied to those methods as well as long as enough second metallic elements or metal based molecules volatile under the growth conditions are supplied.

In yet another embodiment of the present invention the material source 110 may comprise organometallic precursors for providing the second metallic element (e.g. Mg) or metal based molecule—like in CVD and ALD processes—that come in contact with the substrate 130. Upon breaking apart—through the use of temperature, plasma or other chemicals—a metallic state of the second metallic element (e.g. Mg) or metal based molecule may appear at the surface and or excess Mg may be annealed away from the surface upon heating.

In embodiments of the present invention the temperature is one of the parameters of the growth conditions. If the substrate temperature is too low, at least part of the second metallic elements or metal based molecules may remain in the growing film, which can lead to an off stoichiometric condition, and reduced material properties. On the other hand if the substrate temperature is too high—particularly in the case where a Mg cell is used to provide the second metallic element or metal based molecule—no material of the second metallic element or metal based molecule is deposited since all the second metallic elements (e.g. Mg) or metal based molecules will re-evaporate from the substrate. In embodiments of the present invention the controller 120 selects an intermediate substrate temperature wherein part of the deposited second metallic element (e.g. Mg) or metal based molecule on the substrate will re-evaporate. It is thus an advantage of embodiments of the present invention that a dynamic equilibrium condition can be created.

In embodiments of the present invention the pressure is another one of the parameters of the growth conditions. In the case of oxides (first compound and second compound) it can be consisting of O, O2, O3 or other oxygen containing compounds such as water. The applied pressure will determine how much oxygen Is taken up by the film under the growth/annealing conditions. Similarly in the case of nitrides it can be consisting of N, N2 or other nitrogen containing compounds such as NH3.

In an experimental embodiment of the present invention, the controller 120 is configured to regulate the substrate 130 temperature between 20° C. and 1500° C. more preferably between 150° C. and 600° C. more preferably to about 400° C. The second metallic element may for example be Mg evaporating from an effusion cell at about 300° C. in combination with molecular O₂. In this exemplary embodiment the controller 120 may be configured to regulate the oxygen pressure (another parameter of the growth condition) between 10⁻⁷-10⁻⁴ Torr. This oxygen pressure is a suitable oxygen pressure under MBE conditions. It is an advantage of embodiments of the present invention that under these growth conditions an equilibrium can be obtained between some Mg atoms deposited on the surface being re-evaporating while some Mg atoms will react with the O₂ and form MgO. Depending on the oxygen pressure and the growth rate, these growth conditions may lead to component deficient, e.g. oxygen deficient, films. Therefore, in embodiments of the present invention, the controller 120 may be configured to provide a post deposition oxidation anneal experiment after providing the thin film on the substrate 130.

In embodiments of the present invention, the controller 120 is configured to provide a step wherein a higher temperature anneal is performed, in vacuum to remove the excess second metallic element (e.g. Mg) or metal based molecule from the thin film on the substrate 130. In that case the temperature may range between 200° C. and 800° C., preferably between 300° C. and 600° C., and the vacuum pressure may be below 10⁻⁴ Torr, preferably below 10⁻⁷ Torr. This may be done with or without an electrode that has been deposited on top of the thin film. In a preferred embodiment of the present invention the conditions are chosen such that the oxidation and the re-evaporation are in balance to create thin films comprising MgO without defects. It is an advantage of embodiments of the present invention that by providing such an annealing step in vacuum, defects in the film, oxygen excess and oxidation of the substrate 130 can be prevented.

In an exemplary embodiment of the present invention the controller 120 is configured to control the substrate temperature to about 300° C. and the material source 110 provides MgO coming from a high temperature effusion cell or an electron beam gun at about 1500° C. without additional oxygen introduced into the chamber wherein the substrate 130 is positioned. Under MBE growth conditions, the background pressure in the chamber can then be between 10⁻⁷-10⁻⁹ Torr. This condition is different from the previous one since a variety of species such as Mg/O₂/O/MgO are now coming from the substrate. Again the substrate temperature will be a critically determining parameter. In embodiments of the present invention it is put by the controller 120 in a range between 20° C. and 1599° C., preferably between 150° C. and 600° C., preferably at about 400° C. so that some of the Mg will re-evaporate from the substrate and a different resulting stoichiometry compared to the case above is obtained. In embodiments of the present invention, the controller 120 is configured to provide an annealing step after providing the thin film on the substrate. This is advantageous if the stoichiometry of the thin film on the substrate is Mg rich. When performing an annealing in vacuum after the deposition of the thin film, the excess Mg can evaporate. If the stoichiometry of the thin film is component rich, e.g. oxygen rich, the same annealing can remove the excess component, e.g. oxygen.

In embodiments of the present invention the thermodynamic conditions during film growth vary with the thickness of the film. Hence what happens initially during the first few nanometer may not apply for much thicker films. For instance if there is a component deficiency, e.g. an oxygen deficiency, present in the film then a short annealing step can remove the second metallic element (e.g. Mg) or metal based molecule but a for a thicker film more time and effort will be needed for the migration of the excess of the second metallic element (e.g. Mg excess) or metal based molecule. In that case, it could be advantageous to interrupt the deposition process for some time so that the excess of the second metallic element (e.g. Mg) or metal based molecule can evaporate before the rest of the growth proceeds. This interruption could include a quick temperature ramp and change in pressure (different gasses containing oxygen for instance) if needed. The controller 120 can additionally interrupt the growth periodically—for instance by stopping the supplied flux of atoms of the at least one second metallic element (e.g. Mg atoms) or metal based molecule to the substrate 130, or for example to stop the flow of the component (e.g. oxygen) suitable for forming an at least one first compound with the at least one first element and an at least one second compound with the at least one second metallic element or metal based molecule. In embodiments of the present invention this interruption can be done every formed monolayer or unit cell or several unit cells and let the excess species evaporate away. This interruption can be periodic or with any defined timing sequences and it can include changes in substrate temperature or only a partial interruption of the metal as well as component fluxes such as only stopping the flux of the at least one second metallic element (e.g. Mg) or metal based molecule but not the component (e.g. oxygen) flux or vice versa. Such process may lead to a repeated variation of the defect density from for instance component deficient, e.g. oxygen deficient, to component rich, e.g. oxygen rich, wherein gradually a reduced amount of off-stoichiometry is reached at the end of the growth. In embodiments of the present invention the controller 120 is configured to provide a higher temperature annealing step at the end of the growth process in order to improve the overall structure of the film.

In embodiments of the present invention similar compounds comprising a second metallic element (e.g. MgO thin film realizations) or metal based molecule can be made with other source materials or targets for instance in sputtering processes, laser ablation processes, chemical vapour deposition processes.

It is an advantage of embodiments of the present invention that devices and methods according to embodiments of the present invention are generic for all thin film deposition processes. In embodiments of the present invention the controller 120 is configured to control the substrate temperature to the appropriate evaporation temperature of the at least one second metallic element or metal based molecule. For other binary compounds such as for instance SrO and BaO that include a volatile element Sr and Ba, the controller 120 is configured to adjust the substrate temperature to the appropriate evaporation temperature of that specific volatile element. In embodiments of the present invention different material sources 110 can be used. In embodiments of the present invention the material source 110 may for example be used to create either a mono disperse beam of Sr atoms only or a poly-disperse beam containing different elements. In some case this may also consist of a diatomic or triatomic species such as As2 or As3 etc. For compounds involving more elements (for example 3, 4, or even up to 10 elements) this means that the material source 110 may comprise more than one evaporation source. In embodiments of the present invention the material source 110 may comprise multi-element component beams (e.g. H2O, but also chemical precursors such as AsH3 or PH3 or the metalorganic chemical vapour deposition precursors mentioned before like TEOS and Mg(THMD)2).

In an exemplary embodiment of the present invention a compound comprising Mg—Hf—O is created under MBE conditions. In this case the material source 110 for Mg can be anyone of the two sources described above. The material source 110 for Hf can be a target comprising Hf metal or a target comprising HfO₂. For these targets a very high temperature is required to create volatile species with temperatures above 2200° C. Typically this is performed using an electron beam gun, where the temperature is created using the bombardment of electrons on the target material. In embodiments of the present invention the ratio of the different evaporating species can be estimated from collecting the results on a quartz crystal monitor separately for each evaporating species or in a mass spectrometer. In the example a 50/50 ratio between Mg and Hf is preferred. This could lead to a perfect MgHfO₃ compound. In embodiments of the present invention this can be achieved for instance in a co-deposition experiment wherein both MgO and HfO₂ are deposited simultaneously or it can also be done in a sequential manner wherein MgO and HfO₂ fluxes each reach the substrate 130 sequentially. It is an advantage of embodiments of the present invention that If only small amounts and/or ultrathin films are deposited then still homogenous distributions can be achieved. In these embodiments the controller 120 is configured to control the substrate temperature such that at least a fraction (e.g. more than 0.1% or even more than 1% or even more than 10%) of the Mg evaporates during the growth. If the substrate temperature is around 300-400° C. then a fraction of the Mg will evaporate during the growth and dynamic conditions similar to the ones described above will be present. If at the end of the film growth, the stoichiometry is oxygen poor then again an oxygen anneal may be necessary but also in this case a high temperature anneal in vacuum is preferred—using different temperature and times—to remove the excess Mg. By evaporating excess Mg also the perfect stoichiometric MgHfO3 films can be provided. Note that this method does not provide the Mg/Hf stoichiometric 1:1 ratio but provides the correct ratio (Mg+Hf):O ratio.

In an exemplary embodiment of the present invention the first metallic element is aluminum and the second metallic element is magnesium. The added component to create the compounds is oxygen. Oxygen is added in a quantity which is above the stoichiometric quantity for aluminum alone and which is below the stoichiometric quantity of aluminum and magnesium together.

In this exemplary quantitative embodiment the stoichiometric compounds are Al2O3, and MgO. In general, the growth conditions can be oxygen rich or oxygen poor.

In case of Al and O an oxygen rich example is 100 Al atoms and 160 atoms O, and an oxygen poor example is 100 Al atoms and 140 O atoms.

In case of Al, Mg and O combination an oxygen rich example is 80 Al atoms, 30 Mg atoms, 160 O atoms, and an oxygen poor example is 80 Al atoms, 30 Mg atoms, 140 O atoms. In the latter case the 80 Al can consume 120 O atoms to form stoichiometric Al2O3. From the 140 O atoms 20 atoms are left. These bind with the Mg and thus 10 non-oxidised Mg atoms remain. These will evaporate from the surface. Therefore in the oxygen deficient case the Mg controls the stoichiometry.

In a second aspect, the present invention provides a method 200 for providing a thin film on a substrate. The method comprises a step 210 providing:

at least one first metallic element (in embodiments of the present invention this can be multiple element combination) which does not re-evaporate substantially from the substrate under particular growth conditions,

at least one second metallic element or metal based molecule which does re-evaporate substantially from the substrate under the same growth conditions,

a component suitable for forming an at least first compound with the at least one first metallic element and an at least one second compound with the at least one second metallic element or metal based molecule.

The method 200 moreover comprises a step controlling 220 the growth conditions, and the amounts of the at least one first metallic element, of the at least one second metallic element or metal based molecule and of the component so as to obtain a substantially stoichiometric thin film of the at least one first compound and of the at least one second compound on the substrate.

In embodiments of the present invention the provision step 210 and the control step 220 may be done in parallel. The control step 220 may be adapted while growing the thin layer and may be depending on the thickness of this layer.

The provision step 210 and the controlling step 220 may be followed by an annealing step 230. The annealing step 230 may be performed in vacuum or in general at a pressure range or under growth conditions whereby some re-evaporation can take place. The annealing step 230 may be performed to remove the excess of the at least one second metallic element or metal based molecule from the thin film on the substrate. After the annealing step 230 a new provision step 210 and controlling step 220 may follow. This allows to gradually build up and increase the thickness of the thin film.

In embodiments of the present invention the thickness of the obtained thin film may range between 0.2 nm and 100000 nm.

In embodiments of the present invention the at least one first element and the at least one second element may be provided sequentially or simultaneously. When providing 210 them sequentially they may be provided by alternatingly providing the at least one second metallic element or metal based molecule and combinations of the at least one second metallic element or metal based molecule and the at least one first metallic element. During these alterations the substrate temperature may be modified by the control step 220. Also the component fluxes can be varied at different stages and alterations.

1-10. (canceled)

11. A deposition device for providing a thin film on a substrate, wherein the device comprises
a material source for providing at least one first metallic element which does not re-evaporate substantially from the substrate under particular growth conditions, at least one second metallic element or metal based molecule which does re-evaporate substantially from the substrate under the same growth conditions, and a component suitable for forming an at least one first compound with the at least one first metallic element and an at least one second compound with the at least one second metallic element or with the metal based molecule,
a controller configured to control the growth conditions, and the amounts of the at least one first metallic element, the at least one second metallic element or metal based molecule, and the component so as to obtain a substantially stoichiometric thin film of the at least one first compound and of the at least one second compound on the substrate.

12. The deposition device according to claim 11, wherein the controller is configured to provide an annealing step after providing the thin film on the substrate.

13. The deposition device according to claim 11, wherein the controller is configured to alternatingly provide the at least one second metallic element or metal based molecule and combinations of the at least one second metallic element or metal based molecule and the at least one first metallic element, and/or alterations of the component flux, so as to obtain component rich and component deficient states.

14. The deposition device according to claim 13, wherein the controller is configured to change the temperature during the alternations.

15. The deposition device according to claim 11, wherein the controller is configured to control the growth conditions in function of the thickness of the film on the substrate.

16. A method for providing a thin film on a substrate, the method comprising:
providing at least one first metallic element which does not re-evaporate substantially from the substrate under particular growth conditions, providing at least one second metallic element or metal based molecule which does re-evaporate substantially from the substrate under the same growth conditions, providing a component suitable for forming an at least first compound with the at least one first metallic element and an at least one second compound with the at least one second metallic element or metal based molecule,
controlling the growth conditions, and the amounts of the at least one first metallic element, of the at least one second metallic element or metal based molecule and of the component so as to obtain a substantially stoichiometric thin film of the at least one first compound and of the at least one second compound on the substrate.

17. A method according to claim 16, the method comprising an annealing step after providing the elements and controlling the growth conditions.

18. A method according to claim 16, wherein providing the elements is done by alternatingly providing the at least one second metallic element or metal based molecule and combinations of the at least one second metallic element or metal based molecule and the at least one first metallic element.

19. A method according to claim 18, wherein controlling the growth conditions comprises changing the substrate temperature during the alterations.

20. A method according to claim 16, wherein the controlling step comprises taking into account the thickness of the film on the substrate.
